(19) United States
(12) Patent Application Publication
(10) Pub. No.: US 2009/0288702 A1
(43) Pub. Date: Nov. 26, 2009

(54) Solar Cell and Solar Cell Module Using the Same

(76) Inventors: Yun-Gi Kim, Gyeonggi (KR); Doo-Youl Lee, Seoul (KR)

Correspondence Address: MYERS BIGEL SIBLEY & SAJOVEC, PO BOX 37428, RALEIGH, NC, 27627, US

(21) Appl. No.: 12/469,825

(22) Filed: May 21, 2009

Related U.S. Application Data
(63) Continuation of application No. 61/061,341, filed on Jun. 13, 2008.

(30) Foreign Application Priority Data
May 22, 2008 (KR) 2008-47615

(51) Int. Cl. H01L 31/048; H01L 31/00

(52) U.S. Cl. 136/251; 136/256

(57) ABSTRACT

Provided is a solar cell module having improved energy efficiency. The solar cell module includes a frame, first solar cells arranged at the frame, and second solar cells smaller than the first solar cells. The second solar cells are disposed in regions surrounded by the first solar cells. The first solar cells have a substantially circular shape. The second solar cells have a rectangular shape, and each of the second solar cells is surrounded by four of the first solar cells.

### REFERENCE TO PRIORITY APPLICATIONS

This application claims priority from U.S. Provisional Application No. 61/061,341, filed Jun. 13, 2008, and from Korean Patent Application No. 2008-47615, filed May 22, 2008, the disclosures of which are hereby incorporated herein by reference.

### FIELD OF THE INVENTION

The present invention disclosed herein relates to a solar cell, and more particularly, to a solar cell including electrodes on a front surface onto which sunlight is incident and a solar cell module using the solar cell.

### BACKGROUND

In a solar cell, the absorption of light leads to the production of electron-hole pairs in a semiconductor, and an electric field formed at a PN junction of the semiconductor causes the electrons to move to an N-type side of the semiconductor and the holes to move to a P-type side of the semiconductor, thereby generating electricity.

In general, at least one of P-type and N-type electrodes of a solar cell is provided on a back surface of a substrate. If a metal electrode covers a front surface of the substrate, the absorption of sunlight reduces in proportion to the area covered with the metal electrode. This is called a shading loss. A solar cell may be formed using a circular silicon wafer. Referring to FIG. 1, a typical solar cell module is shown, in which solar cells 2 formed of circular silicon wafers may be arranged on a frame 1 in a matrix. However, such an arrangement of solar cells on the frame may lead to dead areas where sunlight can not be absorbed due to the absence of the solar cell. For example, the solar cell module of FIG. 1 may have dead areas equal to or greater than 20% of the total area of the solar cell module.

### SUMMARY

The present invention provides a solar cell module having low dead areas and high energy efficiency.

Embodiments of the present invention provide solar cells. The solar cells may include: a circular solar cell substrate including a front surface and a back surface opposite to the front surface; first and second electrodes at the front surface of the solar cell substrate; and first and second electrode pads disposed at an edge of the solar cell substrate and respectively connected to the first and second electrodes so as to output electricity.

The first and second electrodes may include radially arranged portions.

The first electrode may include: a first main electrode disposed along an edge of the solar cell substrate and having a circular shape; and a plurality of first auxiliary electrodes extending from the first main electrode toward a center of the solar cell substrate. The second electrode may include: a second main electrode disposed at the center of the solar cell substrate and having a circular shape; and a plurality of second auxiliary electrodes extending from the second main electrode toward the edge of the solar cell substrate. The first auxiliary electrodes and the second auxiliary electrodes may be alternatively arranged each other. The first electrode pad may be in contact with the first main electrode, and the second electrode pad may be in contact with one of the second auxiliary electrodes.

The edge of the solar cell substrate may include a pair of mutually facing both of semicircular peripheral portions that are separated by an imaginary diametric line drawn from a first side of the edge to a second side of the edge opposite to the first side. The first electrode may include: a first main electrode at one of the semicircular peripheral portions; and a plurality of first branch electrodes extending from the first main electrode toward the other of the semicircular peripheral portions. The second electrode may include: a second main electrode at the other of the semicircular peripheral portions; and a plurality of second branch electrodes extending from the second main electrode toward the first main electrode.

The edge of the solar cell substrate may include a pair of mutually facing both of semicircular peripheral portions that are separated by an imaginary diametric line drawn from a first side of the edge to a second side of the edge opposite to the first side. The first electrode may include: a first main electrode at one of the semicircular peripheral portions; and a first auxiliary electrode extending from an end of the first main electrode adjacent to the first side of the edge toward the second side of the edge. The second electrode may include: a second main electrode at the other of the semicircular peripheral portions; and a second auxiliary electrode extending from an end of the second main electrode adjacent to the second side of the edge toward the first side of the edge. The second auxiliary electrode may be disposed between the first main electrode and the first auxiliary electrode, and the first auxiliary electrode may be disposed between the second main electrode and the second auxiliary electrode, so as to arrange the first electrode and the second electrode alternatively each other.

The first electrode may further include a plurality of first branch electrodes extending from the first main electrode and the first auxiliary electrode toward the second electrode, and the second electrode may further include a plurality of second branch electrodes extending form the second main electrode and the second auxiliary electrode toward the first electrode.

A distance between the first main electrode and the second auxiliary electrode, a distance between the second auxiliary electrode and the first auxiliary electrode, and a distance between the first auxiliary electrode and the second main electrode are equal to each other.

In some embodiments of the present invention, solar cell modules are provided. The solar cell modules may include a frame, first solar cells on the frame, and second solar cells on regions of the frame surrounded by the first solar cells. The second solar cells may be smaller than the first solar cells.

The first solar cells may have a substantially circular shape. The second solar cells may have a rectangular shape, and each of the second solar cells may be surrounded by four of the first solar cells. The solar cell module may further include third solar cells having a triangular shape formed by cutting the second solar cell along a diagonal line of the second solar cell. The third solar cells may be disposed on exposed edge regions of the frame each surrounded by two of the first solar cells.

In some embodiments of the present invention, solar cell modules may include: a frame; a plurality of first solar cells on the frame, each of the first solar cells including a front surface, a back surface opposite to the front surface, and first and second electrodes on the front surface; and first and second output lines parallel with each other and connected to the first and second electrodes , respectively, the first and second output lines being disposed between the frame and the first solar cells and extending in a direction in which the first solar cells are arranged.

The solar cell module may further include a first electrode pad connecting the first electrode and the first output line; and a second electrode pad connecting the second electrode and the second output line. The first electrode pad and the second electrode pad may be may be disposed at an edge of the frame.

The solar cell module may further include second solar cells on regions of the frame surrounded by the first solar cells, and each of the second solar cells may include a front surface, a back surface opposite to the front surface, and third and fourth electrodes on the front surface. The second solar cells may be smaller than the first solar cells. The first output line may be connected to the fourth electrode, and the second output line may be connected to the third electrode.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 illustrates a conventional solar cell module;

FIGS. 2 through 4 illustrate solar cells according to embodiments of the present invention;

FIGS. 5 and 6 illustrate solar cells according to other embodiments of the present invention;

FIG. 7A illustrates a solar cell module according to an embodiment of the present invention;

FIG. 7B is an enlarged view illustrating a portion of the solar cell module of FIG. 7A;

FIG. 8 illustrates a solar cell module according to another embodiment of the present invention;

FIGS. 9A and 9B are sectional views taken from lines I-I′ and II-II′ of FIG. 7A and FIG. 8;

FIG. 10 illustrates an exemplary solar cell according to an embodiments of the present invention;

FIG. 11 is an enlarged view schematically illustrating portion A of the solar cell of FIG. 10; and

FIG. 12 illustrates an exemplary of a solar cell power generating system using a solar cell module according to embodiments of the present invention.

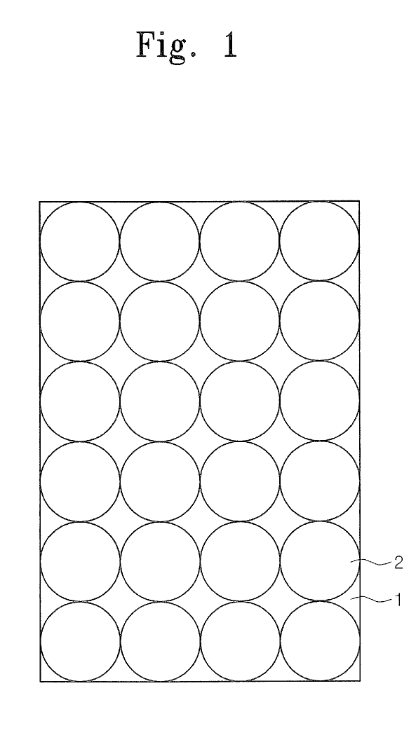

### DETAILED DESCRIPTION OF EXEMPLARY EMBODIMENTS

Objects, other objects, features and advantages of the present invention will be easily appreciated through exemplary embodiments with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the specification, it will be understood that when an object is referred to as being ‘on’ another object or substrate, it may be directly on the other object or substrate, or intervening objects may also be present. Also, in the figures, the dimensions of objects and regions are exaggerated for clarity of illustration. Also, though terms like a first, a second, and a third are used to describe various objects in various embodiments of the present invention, the objects are not limited to these terms. These terms are used only to discriminate one object from another object. An embodiment described and exemplified herein includes a complementary embodiment thereof. Reference numeral used to denote an element in one embodiment may also be used to denote the same or similar element in another embodiment.

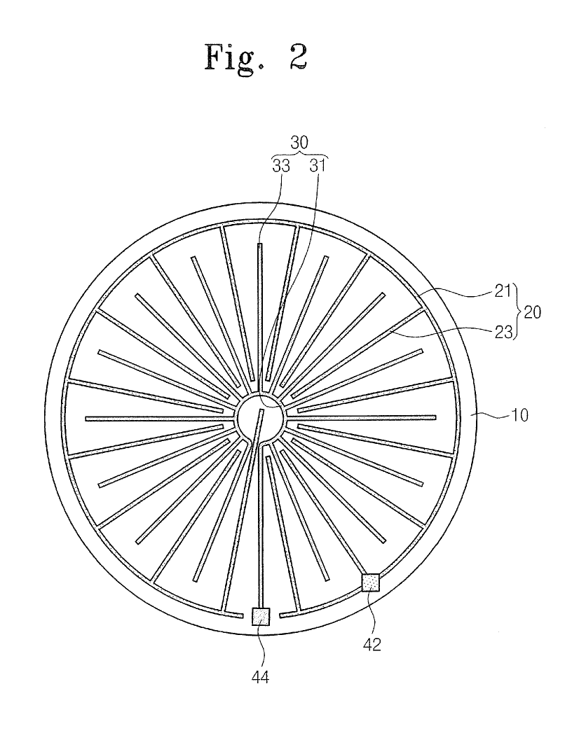

Referring to FIGS. 2 through 4, solar cells according to exemplary embodiments of the present invention, and in particular arrangements of electrodes on the front surfaces of the solar cells will be described. The solar cells may include a circular solar cell substrate 10, a first electrode 20, a second electrode 30, a first electrode pad 42, and a second electrode pad 44. The solar cell substrate 10 may include a front surface for receiving sunlight and a back surface opposite to the front surface. The first and second electrodes 20 and 30 may be disposed on the front surface of the solar cell substrate 10. The first and second electrode pads 42 and 44 may be disposed on an edge of the solar cell substrate 10. The solar cell substrate 10 may have a vertical structure of an embodiment of FIG. 10 (described later). The first electrode pad 42 and the second electrode pad 44 may be connected to the first electrode 20 and the second electrode 30, respectively, for supplying electricity to an outside area. For example, the first electrode 20 and the second electrode 30 may be a P-type electrode and an N-type electrode, respectively.

Referring to FIG. 2, in an embodiment, the first and second electrodes 20 and 30 of the solar cell may include radially arranged portions. For example, the first electrode 20 may include a first main electrode 21 disposed along an edge of the solar cell substrate 10 in a circular shape and a plurality of first auxiliary electrodes 23 extending from the first main electrode 21 to a center portion of the solar cell substrate 10. The first main electrode 21 may have an open circular shape. The second electrode 30 may include a second main electrode 31 and a plurality of second auxiliary electrodes 33. The second main electrode 31 may be disposed in the center portion of the solar cell substrate 10. The second auxiliary electrodes 33 may extend from the second main electrode 31 toward the edge of the solar cell substrate 10. The second main electrode 31 may have an open circular shape. The first auxiliary electrodes 23 and the second auxiliary electrodes 33 may be arranged in an alternating manner. The distance between the first auxiliary electrodes 23 and the second auxiliary electrodes 33 may increase in a direction from the center portion to the edge of the solar cell substrate 10. The solar cell may further include a plurality of first branch electrodes (not shown) extending from the first auxiliary electrodes 23 toward the second auxiliary electrodes 33. The solar cell may further include a plurality of second branch electrodes (not shown) extending from the second auxiliary electrodes 33 toward the first auxiliary electrodes 23. The first branch electrodes and the second branch electrodes may be arranged in an alternating manner.

The first electrode pad 42 may be in contact with the first main electrode 21, and the second electrode pad 44 may be in contact with one of the first auxiliary electrodes 23.

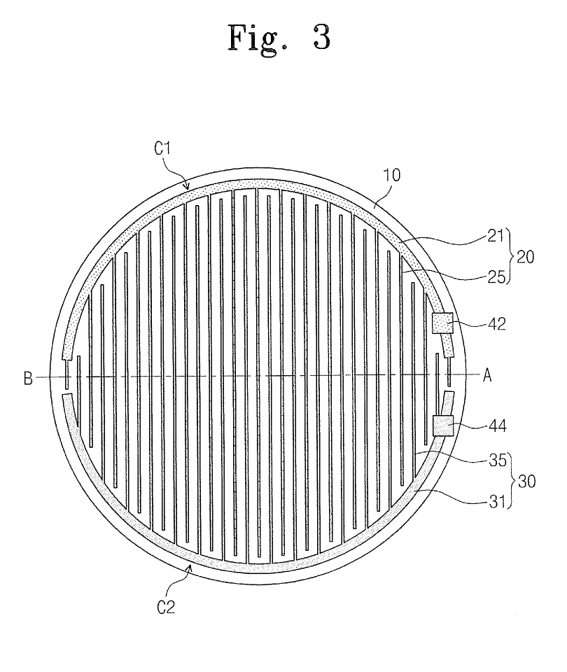

Referring to FIG. 3, other embodiment of the solar cell will now be described. The solar cell of FIG. 3 may include the same elements as those of the solar cell of FIG. 2, and descriptions of the same elements may be omitted. The edge of the solar cell substrate 10 may include a pair of mutually facing semicircular peripheral portions C1 and C2 that are separated by a diametric line AB drawn from one side A to the opposite side B of the edge of the solar cell substrate 10. The first electrode 20 may include a first main electrode 21 disposed on the semicircular peripheral portion C1 and a plurality of first branch electrodes 25 extending from the first main electrode 21 toward the semicircular peripheral portion C2 opposite to the semicircular peripheral portion Cl. The second electrode 30 may include a second main electrode 31 disposed on the semicircular peripheral portion C2 and a plurality of second branch electrodes 35 extending from the second main electrode 31 toward the semicircular peripheral portion C1. The first branch electrodes 25 and the second branch electrodes 35 may be arranged in an alternating manner.

The first electrode pad 42 may be in contact with the first main electrode 21, and the second electrode pad 44 may be in contact with the second main electrode 31.

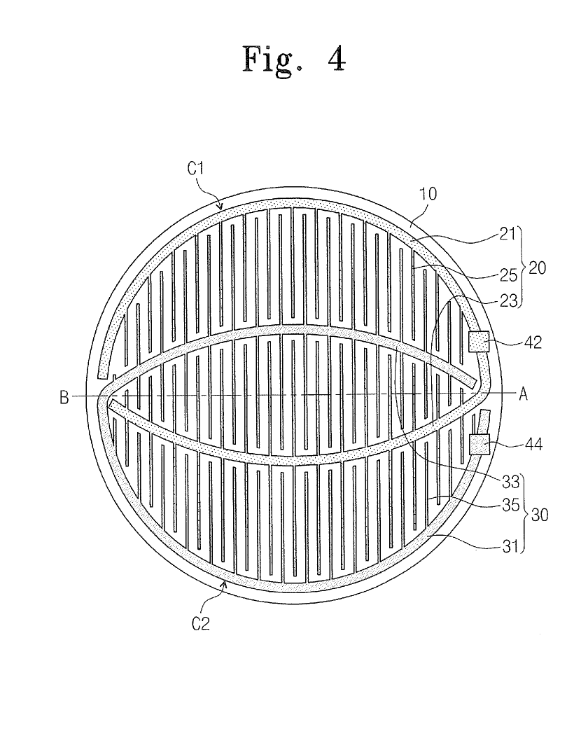

Referring to FIG. 4, another embodiment of the solar cell will now be described. The solar cell of FIG. 4 may include the same elements as those of the solar cell of FIG. 2, and descriptions of the same elements may be omitted. The edge of the solar cell substrate 10 may include a pair of mutually facing semicircular peripheral portions C1 and C2 that are separated by a diametric line AB drawn from one side A to the opposite side B of the edge of the solar cell substrate 10. The first electrode 20 may include a first main electrode 21 and a first auxiliary electrode 23. The first main electrode 21 may be disposed on the semicircular peripheral portion Cl. The first auxiliary electrode 23 may extend from one end of the first main electrode 21 adjacent to the side A toward the opposite side B. The second electrode 30 may include a second main electrode 31 and a second auxiliary electrode 33. The second main electrode 31 may be disposed on the semicircular peripheral portion C2. The second auxiliary electrode 33 may extend from an end of the second main electrode 31 adjacent to the opposite side B toward the side A. The second auxiliary electrode 33 may be disposed between the first main electrode 21 and the first auxiliary electrode 23, and the first auxiliary electrode 23 may be disposed between the second main electrode 31 and the second auxiliary electrode 33. In this way, the first electrode 20 and the second electrode 30 may be arranged in an alternating manner.

The distance between the first main electrode 21 and the second auxiliary electrode 33, the distance between the second auxiliary electrode 33 and the first auxiliary electrode 23, and the distance between the first auxiliary electrode 23 and the second main electrode 31 may be equal to each other.

The first electrode 20 may further include a plurality of first branch electrodes 25 extending from the first main electrode 21 and the first auxiliary electrode 23 toward the second electrode 30. The second electrode 30 may further include a plurality of second branch electrodes 35 extending from the second main electrode 31 and the second auxiliary electrode 33 toward the first electrode 20. The first branch electrodes 25 and the second branch electrodes 35 may be arranged in an alternating manner.

The first electrode pad 42 may be in contact with the first main electrode 21, and the second electrode pad 44 may be in contact with second main electrode 31.

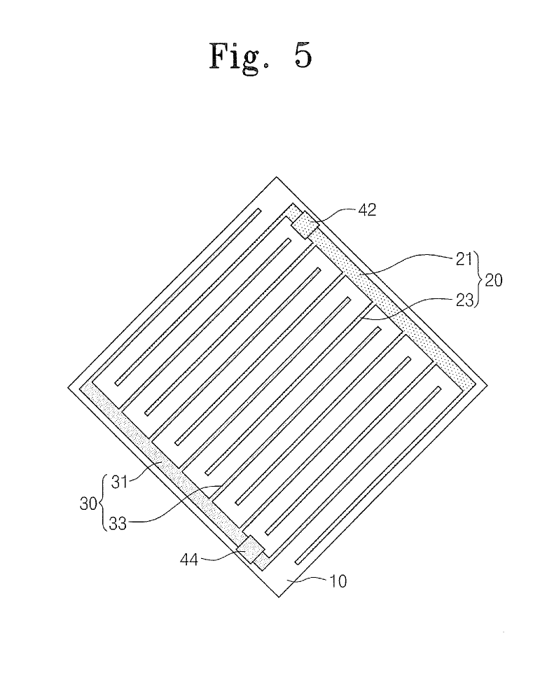

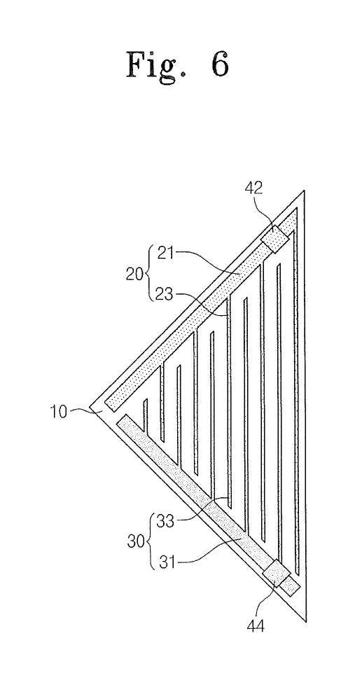

FIGS. 5 and 6 illustrate solar cells according to modified embodiments of the present invention. Referring to FIG. 5, a rectangular solar cell is provided. Four sides of the rectangular solar cell may have the same length. First and second electrodes 20 and 30 are disposed on a front surface of the rectangular solar cell. The first electrode 20 may include a first main electrode 21 and first auxiliary electrodes 23. The second electrode 30 may include a second main electrode 31 and second auxiliary electrodes 33. The first main electrode 21 and the second main electrode 31 may be disposed on a pair of mutually facing edges of the rectangular solar cell, respectively. The first auxiliary electrodes 23 may extend from the first main electrode 21 toward the second main electrode 31. The second auxiliary electrodes 33 may extend from the second main electrode 31 toward the first main electrode 21. The first auxiliary electrodes 23 and the second auxiliary electrodes 33 may be arranged in an alternating manner. A first electrode pad 42 may be in contact with the first main electrode 21, and a second electrode pad 44 may be in contact with the second main electrode 31.

Referring to FIG. 6, a triangular solar cell is provided. First and second electrodes 20 and 30 are disposed on a front surface of the triangular solar cell. The first electrode 20 may include a first main electrode 21 and first auxiliary electrodes 23. The second electrode 30 may include a second main electrode 31 and second auxiliary electrodes 33. The first main electrode 21 and the second main electrode 31 may be disposed on a pair of adjacent edges of the triangular solar cell, respectively. The first auxiliary electrodes 23 may extend from the first main electrode 21 toward the second main electrode 31. The second auxiliary electrodes 33 may extend from the second main electrode 31 toward the first main electrode 21. The first auxiliary electrodes 23 and the second auxiliary electrodes 33 may be arranged in an alternating manner.

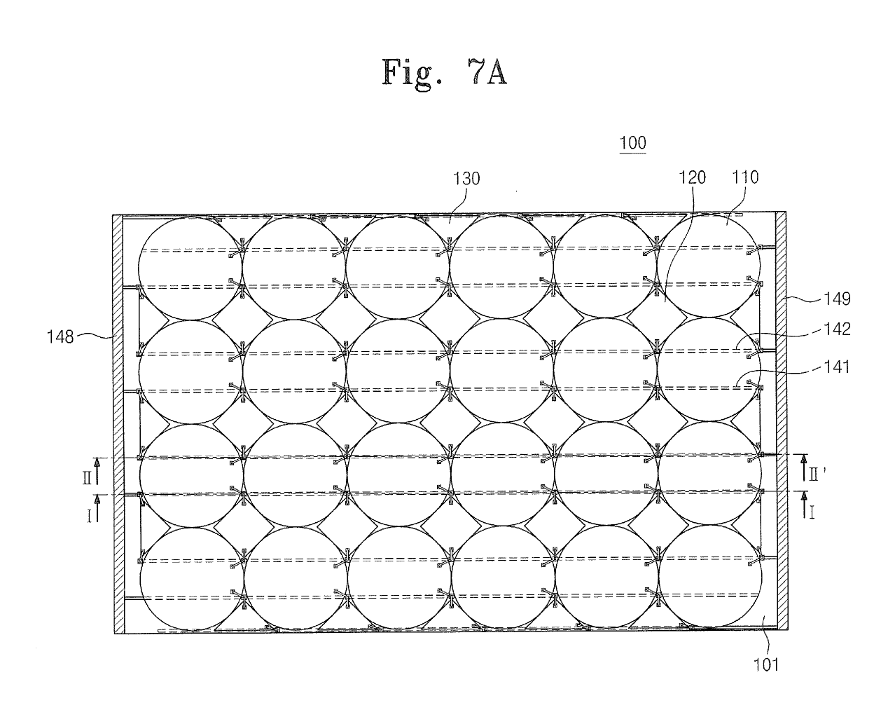

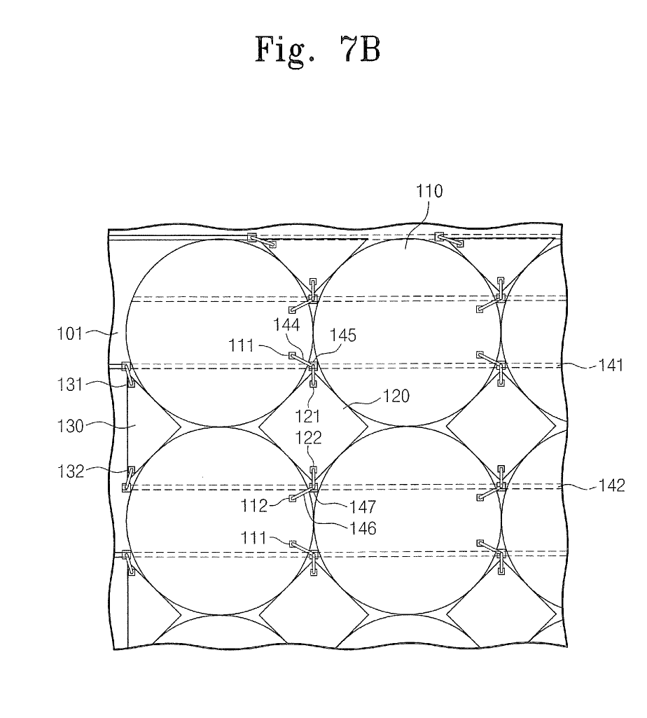

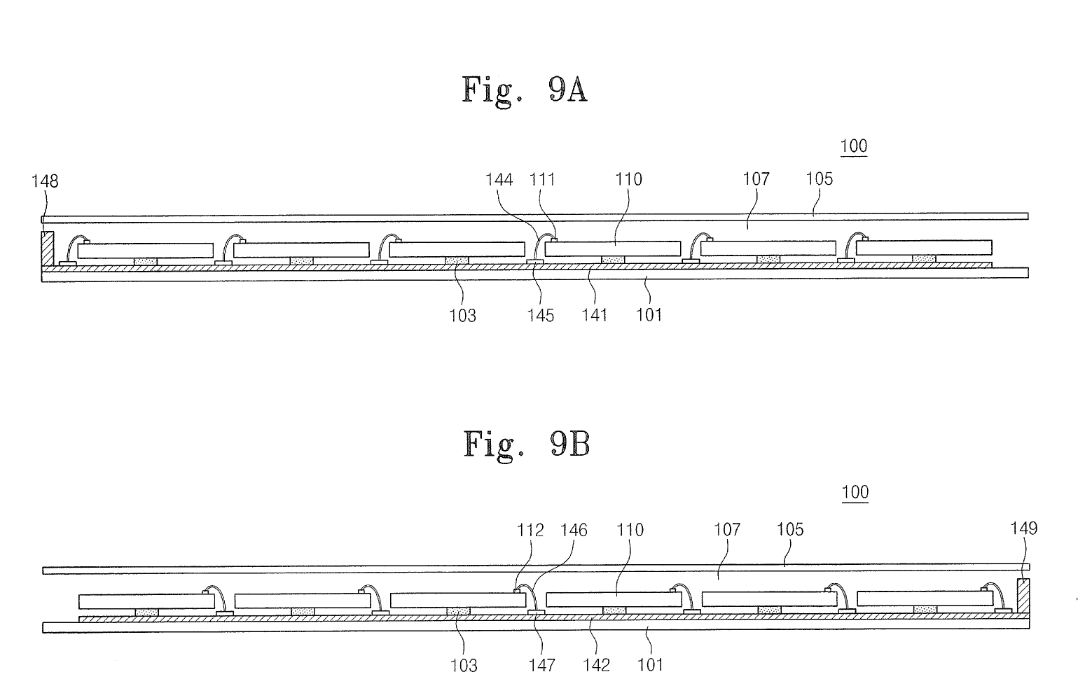

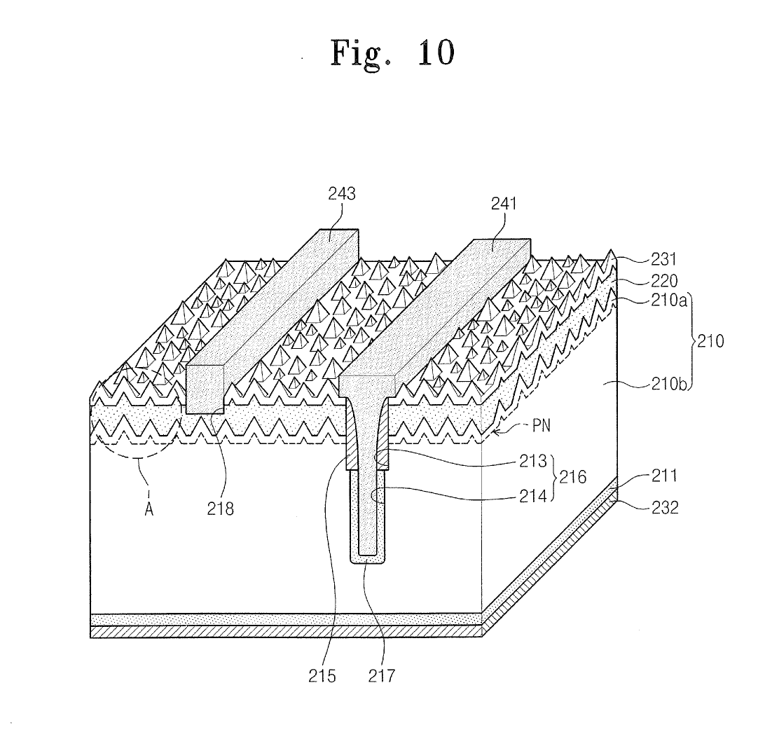

A solar cell module 100 will now be described with reference to FIGS. 7A, 7B, 9A, and 9B according to an embodiment of the present invention. The solar cell module 100 may include a frame 101, first solar cells 110 arranged on the frame 101, and second solar cells 120 having a size or shape different from that of the first solar cells 110. The first and second solar cells 110 and 120 may be supported by support portions 103 disposed on the frame 101. The first solar cells 110 may be arranged in matrix format.

The first solar cells 110 may have a circular shape like the solar cells illustrated in FIGS. 2 through 4. For example, the first solar cells 110 may be solar cells formed on silicon wafers. The second solar cells 120 may be smaller than the first solar cells 110. The second solar cells 120 may have a rectangular shape. Each of the second solar cells 120 may be disposed in a region surrounded by four first solar cells 110. For example, the second solar cells 120 may have the same structure as the solar cell illustrated in FIG. 5. The solar cell module 100 may further include third solar cells 130 having a triangular shape, which can be formed by cutting the rectangular second solar cell 120 in half along its diagonal line. For example, the third solar cells 130 may have the same structure as the solar cell illustrated in FIG. 6. The third solar cells 130 may be disposed on exposed edges of the frame 101 each surrounded by two first solar cells 110. For example, if the first solar cells 110 are 8 inches in diameter, one side of each of the second solar cells 120 may be 3.2 inches in length. If the first solar cells 110 are 12 inches in diameter, one side of each of the second solar cells 120 may be 5 inches in length.

Each of the first solar cells 110, the second solar cells 120, and the third solar cells 130 may include a front surface for receiving sunlight and a back surface opposite to the front surface. First and second electrodes (not shown) may be disposed on the front surface of each of the solar cells 110, 120, and 130. For example, the first and second electrodes may be P-type and N-type electrodes, respectively. The first and second electrodes may be arranged like the first and second electrodes illustrated in any one of FIGS. 2 through 6. An exemplary structure of the solar cells 110, 120, and 130 is illustrated in FIG. 10 according to an embodiment of the present invention.

The solar cell module 100 may further include first electrode pads 111, 121, and 131, and second electrode pads 112, 122, and 132 that are disposed on edges of the solar cells 110, 120, and 130. The first electrode pads 111, 121, and 131 may be connected to the first electrodes (not shown) of the solar cells 110, 120, and 130. The second electrode pads 112, 122, and 132 may be connected to the second electrodes (not shown) of the solar cells 110, 120, and 130. The solar cell module 100 may further include first output lines 141 and second output lines 142 that are parallel with each other. The first and second output lines 141 and 142 may be disposed between the frame 101 and the first solar cells 110 and may extend in a direction in which the first solar cells 110 are arranged. The first electrode pads 111, 121, and 131 may connect the first electrodes to the first output lines 141 through first connection wires 144 and first connection taps 145. The second electrode pads 112, 122, and 132 may connect the second electrodes to the second output lines 142 through second connection wires 146 and second connection taps 147. The first and second connection taps 145 and 147 may be disposed in regions surrounded by the solar cells 110, 120, and 130 and be in electric contact with the first and second output lines 141 and 142.

A first terminal 148 may be disposed on an edge of one side of the frame 101, and a second terminal 149 may be disposed on an edge of the other side of the frame 101. The first terminal 148 may be connected to ends of the first output lines 141 and the second terminal 149 may be connected to ends of the second output lines 142 for outputting electricity.

A glass cover 105 may be disposed on front side of the solar cells 110, 120, and 130 for protecting the solar cells 110, 120, and 130. An ethyl vinyl acetate (EVA) sheet 107 may be disposed between the glass cover 105 and the frame 101.

In the current embodiment having the arrangement of the solar cells 110, 120, and 130, dead areas of the solar cell module 100 can be reduced to a level equal to or less than about 5% of the total area of the solar cell module 100. In the current embodiment, both the first and second electrodes (P-type and N-type electrodes) are provided on the front surfaces of the solar cells 110, 120, and 130 so that the first and second connection wires 144 and 146, the first and second connection taps 145 and 147, and the first and second output lines 141 and 142 can be arranged with minimum space loss. Therefore, the solar cell module 100 can have high energy efficiency.

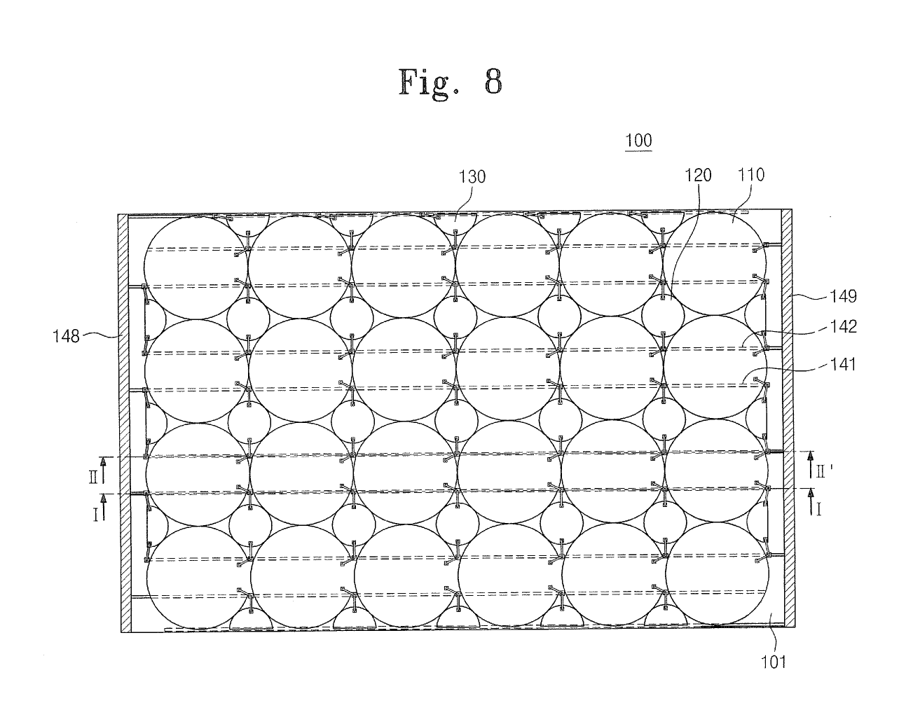

In the current embodiment, the second solar cells 120 have a rectangular shape, and the third solar cells 130 have a triangular shape. However, the second solar cells 120 are not limited to the rectangular shape, and the third solar cells 130 are not limited to the triangular shape. That is, the shapes and sizes of the second and third solar cells 120 and 130 may be varied as long as the second and third solar cells 120 and 130 can be disposed in exposed regions of the frame 101 between the first solar cells 110. For example, the second solar cells 120 may have a circular or triangular shape, and the third solar cells 130 may have a semicircular shape. In another embodiment shown in FIGS. 8, 9A, and 9B, the second solar cells 120 have a circular shape, and the third solar cells 130 have a semicircular shape. The third solar cells 130 may have a semicircular shape formed by cutting the second solar cell 120 in half along a diametric line of the second solar cell 120. In this case, the solar cell module 100 may have dead areas equal to about 8.5% of the total area of the solar cell module 100.

Referring to FIG. 10, an exemplary solar cell according to embodiments of the present invention. The solar cell may include a first conductive type semiconductor substrate 210 (hereinafter, also referred to as ‘semiconductor substrate’ in brief). The first conductive type semiconductor substrate 210 may include a front surface for receiving sunlight and a back surface opposite to the front surface. The front surface of the semiconductor substrate 210 may be textured into a concave-convex structure having a regularly arranged inverse pyramid pattern. Owing to the concave-convex structure having a regularly arranged inverse pyramid pattern, the solar cell can have high light absorptivity as compared with the case where the first conductive type semiconductor substrate 210 has a flat front surface. The solar cell may further include a second conductive type semiconductor layer 220 (hereinafter, also referred to as ‘semiconductor layer’ in brief) and an anti-reflective layer 231. The second conductive type semiconductor layer 220 is disposed on the first conductive type semiconductor substrate 210, and the anti-reflective layer 231 is disposed on the second conductive type semiconductor layer 220. The second conducive type is opposite to the first conductive type.

The first conductive type semiconductor substrate 210 may be formed of single crystal silicon, and the second conductive type semiconductor layer 220 may be formed of amorphous silicon. The first conductive type may be a P-type and the second conductive type may be an N-type. A PN junction may be formed adjacent to a boundary between the first conductive type semiconductor substrate 210 and the second conductive type semiconductor layer 220. For example, the PN junction may be formed in the semiconductor substrate 210 adjacent to the boundary. The PN junction may be a shallow junction. The PN junction may have a depth of several angstroms (Å) to about 1,000□. For example, the PN junction may have a depth of about 600 Å. In this case, electron migration can be minimized so that the possibility of electron dissipation caused by recombination can be reduced.

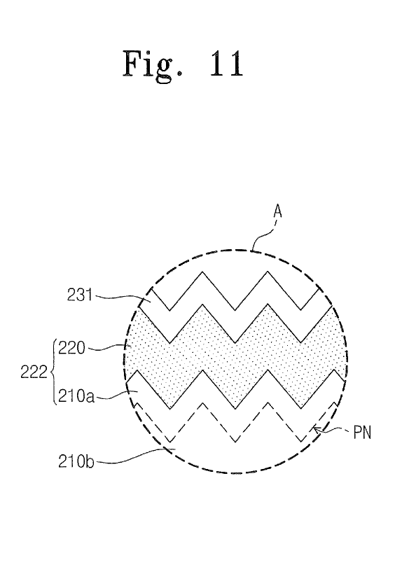

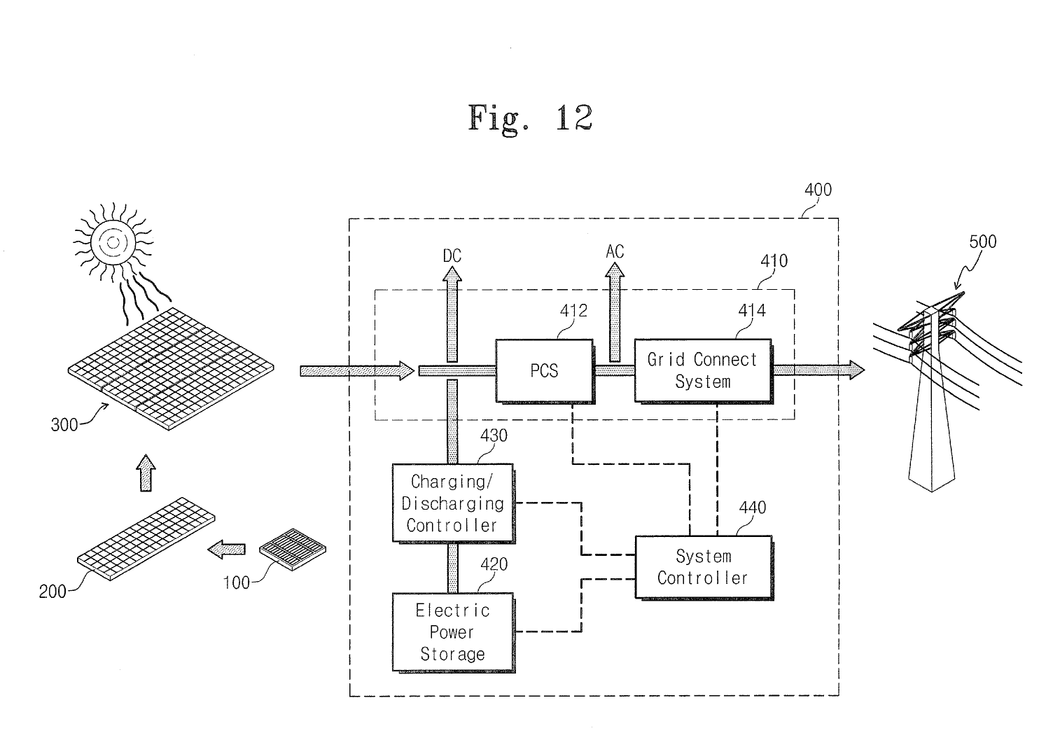

The semiconductor layer 220 may be heavily doped with impurity ions of the second conductive type. The semiconductor layer 220 may have an impurity ion concentration in the range from about 10¹⁹/cm³ to about 10²¹/cm³. Referring to FIG. 11, the first conductive type semiconductor substrate 210 may include a boundary region 210a in its upper portion adjoining the second conductive type semiconductor layer 220. The boundary region 210a may be heavily doped with impurity ions of the second conductive type. The boundary region 210a may be formed by impurity ions diffused from the second conductive type semiconductor layer 220 to the first conductive type semiconductor substrate 210. Accordingly, the semiconductor substrate 210 may include a base region 210b of the first conductive type at its lower portion, and the boundary region 210a of the second conductive type at its upper portion. The PN junction may be formed between the first conductive type boundary region 210a and the second conductive type base region 210b. The boundary region 210a may have an impurity ion concentration lower than that of the semiconductor layer 220.

The boundary region 210a and the semiconductor layer 220 may be designated as a second conductive region 222. The impurity concentration of the second conductive region 222 may increase sequentially. Furthermore, since the solar cell of the current embodiment has a heterojunction between the first conductive type amorphous semiconductor layer 220 and the second conductive type crystalline semiconductor substrate 210, the solar cell can absorb light in a wider wavelength band.

The anti-reflective layer 231 may have an optical thickness equal to quarter the wavelength of incident light. In this case, since the anti-reflective layer 231 can be an anti-reflection coating that may not reflect incident light, the reflectance of the anti-reflective layer 231 can be reduced. The anti-reflective layer 231 may have a double layer structure to reduce a thickness error as compared with the case where the anti-reflective layer 231 has a single layer structure. The anti-reflective layer 231 may include a silicon oxide layer, a silicon nitride layer or a multilayer thereof. The anti-reflective layer 231 may protect the front surface of the solar cell.

Referring again to FIG. 10, the solar cell may further include a first electrode 241 and a second electrode 243 that are disposed at the front surface of the first conduction type semiconductor substrate 210. The first electrode 241 may be electrically connected to the base region 210b of the first conductive type semiconductor substrate 210, and the second electrode 243 may be electrically connected to the second conductive type semiconductor layer 220. The first electrode 241 may be disposed in a first trench 216 exposing the base region 210b of the first conductive type semiconductor substrate 210. The second electrode 243 may be disposed in a second trench 218, which is shallower than the first trench 216 and exposes the second conductive type semiconductor layer 220. A bottom surface of the second trench 218 may be higher than a top surface of the semiconductor substrate 210 so as not to expose the semiconductor substrate 210 through the second trench 218. It may be sufficient that the first trench 216 has a depth smaller than the thickness of the semiconductor substrate 210. For example, the depth of the first trench 216 may be equal to or smaller than about ⅔ of the thickness of the semiconductor substrate 210. The first and second trenches 216 and 218 may have a width equal to or smaller than about 1 μm.

A dielectric spacer 215 may be disposed on a sidewall of an upper portion 213 of the first trench 216 and expose the base region 210b of the first conductive type semiconductor substrate 210. The dielectric spacer 215 may include a silicon oxide layer, a silicon nitride layer or a multilayer thereof. The dielectric spacer 215 may separate the first electrode 241 from the second conductive type semiconductor layer 220 to prevent a direct contact between the second conductive type semiconductor layer 220 and the first electrode 241. The dielectric spacer 215 may extend downward to a position equal to or deeper than the position of the PN junction. The first trench 216 may have an extension trench 214, which is coplanar with an inner wall of the dielectric spacer 215 and extends toward the back surface of the semiconductor substrate 210.

To reduce contact resistance between the first electrode 241 and the base region 210b of the first conductive type semiconductor substrate 210, a first conductive type impurity layer 217 having a high impurity concentration may be formed on the sidewall and the bottom surface of the first trench 216. The first conductive type impurity layer 217 may be formed on a portion of the first conductive type semiconductor substrate 210 uncovered with the dielectric spacer 215. That is, the first conductive type impurity layer 217 may be formed on the extension trench 214.

The first and second electrodes 241 and 243 may be aluminum (Al), copper (Cu), nickel (Ni), tungsten (W), titanium (Ti), titanium nitride (TiN), tungsten nitride (WN), metal silicide, or a multilayer thereof. For example, the first and second electrodes 241 and 243 may have a multilayered structure of Ti/TiN/Al or Ti/TiN/W. The first and second electrodes 241 and 243 may be arranged in an alternating manner.

Since the first electrode 241 is disposed in the first trench 216, it is possible to increase a contact area between the first electrode 241 and the base region 210b of the semiconductor substrate 210, and thus contact and surface resistances between the first electrode 241 and the base region 210b can be reduced. In addition, energy conversion efficiency of the solar call can be increased because electrons can be easily trapped to the first electrode 241.

A back surface field (BSF) impurity layer 211 may be disposed on the back surface of the semiconductor substrate 210. The BSF impurity layer 211 may be used to form a back surface field so as to facilitate collection of a current. The BSF impurity layer 211 may be an impurity layer heavily doped with impurity ions of the first conductive type. In the current embodiment of the present invention, since both the first and second electrodes 241 and 243 are disposed at the front surface of the semiconductor substrate 210, it is possible to omit the BSF impurity layer 211. A protective dielectric layer 232 may be disposed on the back surface of the first conductive type semiconductor substrate 210. For example, the protective dielectric layer 232 may cover the BSF impurity layer 211 entirely. The protective dielectric layer 232 may be formed of the same material as that used for forming the dielectric spacer 215. The protective dielectric layer 232 may prevent light, which is incident onto the front surface of the semiconductor substrate 210 and passes through the semiconductor substrate 210, from being transmitted through the back surface of the semiconductor substrate 210. That is, the protective dielectric layer 232 may reflect the light toward the front surface of the first conductive type semiconductor substrate 210. The light reflected from the protective dielectric layer 232 may be reflected again by the anti-reflective layer 231. In this way, light incident onto the first conductive type semiconductor substrate 210 may be confined within the semiconductor substrate 210. Unlike conventional solar cells, both the first and second electrodes 241 and 243 are disposed at the front surface of the semiconductor substrate 210 in the solar cell of the current embodiment so that a portion exposing the semiconductor substrate 210 may not exist in the protective dielectric layer 232. Since light can be reflected by the entire back surface of the semiconductor substrate 210, the reflectance of the back surface of the semiconductor substrate 210 can be increased more effectively.

A photovoltaic system using a solar cell module will now be described with reference to FIG. 12 according to embodiments of the present invention. Since solar cells according to embodiments of the present invention may output a voltage of about 0.5 V, a solar cell module 200 is implemented by connecting a plurality of solar cells in parallel and/or in series to obtain a desired voltage level. A solar cell array 300 may be implemented by installing a plurality of solar cell modules 200 on a frame (not shown). The solar cell array 300 may be fixed to the frame and oriented toward the south at a predetermined angle to receive more sunlight.

The photovoltaic system may include the solar cell array 300 and a power controller 400 configured to receive power from the solar cell array 300 and output it to the outside. The power controller 400 may include an output device 410, an electric power storage 420, a charging/discharging controller 430, and a system controller 440. The output device 410 may include a power conditioning system (PCS) 412 and a grid connect system 414. The PCS 412 may be an inverter converting a direct current (DC) generated from the solar cell array 300 to an alternating current (AC). The grid connect system 414 may be connected to another power system 500. Since the sun does not shine at night and shines little on cloudy days, generation of power may stop or reduce during those times. Thus, the condenser 420 is provided to store electricity and output stored electricity so as to prevent the power supplying ability of the photovoltaic system from varying according to weather conditions. The charging/discharging controller 430 may be used to store power generated from the solar cell array 300 to the electric power storage 420 and output the electricity stored in the electric power storage 420 to the output device 410. The system controller 440 may be used to control the output device 410, the electric power storage 420, and the charging/discharging controller 430.

According to the present invention, the dead areas of the solar cell module can be reduced. Particularly, since both the P-type and N-type electrodes are disposed on the front surfaces of the solar cells, the connection wires, the connection taps, and the output lines can be arranged with minimum space loss. Therefore, the solar cell module can have high energy efficiency.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

1.-11. (canceled)

12. A solar cell comprising:
a circular solar cell substrate comprising a front surface and a back surface opposite to the front surface;
first and second electrode on the front surface of the solar cell substrate; and
first and second electrode pad disposed at an edge of the solar cell substrate and respectively connected to the first and second electrodes so as to output electricity.

13. The solar cell of claim 12, wherein the first and second electrodes comprise radially arranged portions.

14. The solar cell of claim 13, wherein the first electrode comprises:
a first main electrode disposed along the edge of the solar cell substrate and having a circular shape; and
a plurality of first auxiliary electrodes extending from the first main electrode toward a center portion of the solar cell substrate.

15. The solar cell of claim 14, wherein the second electrode comprises:
a second main electrode disposed at the center portion of the solar cell substrate and having a circular shape; and
a plurality of second auxiliary electrodes extending from the second main electrode toward the edge of the solar cell substrate.

16. The solar cell of claim 15, wherein the first auxiliary electrodes and the second auxiliary electrodes are arranged in an alternating manner.

17. The solar cell of claim 15, wherein the first electrode pad is in contact with the first main electrode, and the second electrode pad is in contact with one of the second auxiliary electrodes.

18. The solar cell of claim 12, wherein the edge of the solar cell substrate comprises a pair of mutually facing semicircular peripheral portions that are separated by an imaginary diametric line drawn from a first side of the edge to a second side of the edge opposite to the first side,
wherein the first electrode comprises:
a first main electrode on one of the semicircular peripheral portions; and
a plurality of first branch electrodes extending from the first main electrode toward the other of the semicircular peripheral portions,
wherein the second electrode comprises:
a second main electrode on the other of the semicircular peripheral portions; and
a plurality of second branch electrodes extending from the second main electrode toward the first main electrode.

19. The solar cell of claim 12, wherein the edge of the solar cell substrate comprises a pair of mutually facing semicircular peripheral portions that are separated by an imaginary diametric line drawn from a first side of the edge to a second side of the edge opposite to the first side,
wherein the first electrode comprises:
a first main electrode on one of the semicircular peripheral portions; and
a first auxiliary electrode extending from an end of the first main electrode adjacent to the first side of the edge toward the second side of the edge,
wherein the second electrode comprises:
a second main electrode on the other of the semicircular peripheral portions; and
a second auxiliary electrode extending from an end of the second main electrode adjacent to the second side of the edge toward the first side of the edge,
wherein the second auxiliary electrode is disposed between the first main electrode and the first auxiliary electrode, and the first auxiliary electrode is disposed between the second main electrode and the second auxiliary electrode, so as to arrange the first electrode and the second electrode in an alternating manner.

20. The solar cell of claim 19, wherein the first electrode further comprises a plurality of first branch electrodes extending from the first main electrode and the first auxiliary electrode toward the second electrode, and
the second electrode farther comprises a plurality of second branch electrodes extending form the second main electrode and the second auxiliary electrode toward the first electrode.

21. The solar cell of claim 19, wherein a distance between the first main electrode and the second auxiliary electrode, a distance between the second auxiliary electrode and the first auxiliary electrode, and a distance between the first auxiliary electrode and the second main electrode are equal to each other.

22. A solar cell module comprising:
a frame;
first solar cells at the frame; and
second solar cells in regions of the frame surrounded by the first solar cells, the second solar cells being smaller than the first solar cells.

23. The solar cell module of claim 22, wherein the first solar cells have a substantially circular shape.

24. The solar cell module of claim 23, wherein the second solar cells have a rectangular shape, and each of the second solar cells is surrounded by four of the first solar cells.

25. The solar cell module of claim 24, further comprising third solar cells having a triangular shape formed by cutting the second solar cell along a diagonal line of the second solar cell, the third solar cells being disposed in exposed edge regions of the frame each surrounded by two of the first solar cells.

26. A solar cell module comprising:
a frame;
a plurality of first solar cells at the frame, each of the first solar cells comprising a front surface, a back surface opposite to the front surface, and first and second electrodes on the front surface; and
first and second output lines parallel with each other and connected to the first and second electrodes, respectively, the first and second output lines being disposed between the frame and the first solar cells and extending in a direction in which the first solar cells are arranged.

27. The solar cell module of claim 26, and the solar cell module further comprises:
a first electrode pad connecting the first electrode and the first output line; and
a second electrode pad connecting the second electrode and the second output line, wherein the first electrode pad and the second electrode pad are disposed at an edge of the frame,

28. The solar cell module of claim 27, further comprising second solar cells in regions of the frame surrounded by the first solar cells, each of the second solar cells comprising a front surface, a back surface opposite to the front surface, and third and fourth electrodes on the front surface, the second solar cells being smaller than the first solar cells.

29. The solar cell module of claim 28, wherein the first output line is connected to the fourth electrode, and the second output line is connected to the third electrode.
